(19) United States
(12) Patent Application Publication
(10) Pub. No.: US 2006/0245152 A1
(43) Pub. Date: Nov. 2, 2006

(54) Handheld electronic device casing element

(76) Inventor: Tejal Chauhan, Middlesex (GB)

Correspondence Address: HARRINGTON & SMITH, LLP, 4 RESEARCH DRIVE, SHELTON, CT, 06484-6212, US

(21) Appl. No.: 10/563,593

(22) PCT Filed: Jul. 8, 2003
(86) PCT No.: PCT/GB03/02939

§ 371 Date: Apr. 20, 2006

(51) Int. Cl. G06F 1/16; H05K 7/00

(52) U.S. Cl. 361/681

(57) ABSTRACT

A detachable trim element for a handheld electronic device. The trim element includes a bumper providing an external surface of the device, and push-fit attachments to connect the bumper to the sides of the casing.

The invention relates to casing elements for handheld devices and user interfaces therefor. The invention also relates to handheld devices and user removable elements therefor.

With the advent of additional functionality for mobile or handheld communication devices, there are increasing pressures on the user interface to allow the user to access the functionalities as easily and effectively as possible. This is a particular problem when there are a number of primary functions that a device provides.

With the mass market appeal of radio telephones, there continues to be a need amongst consumers to express their individuality with, or impose their character on, these devices. User replaceable A and B covers go only so far towards meeting this need.

In accordance with the present invention there is provided a detachable trim element for a handheld electronic device having a casing enclosing the engine of the device and providing first and second opposed faces bridged by a side portion, the trim element comprising a bumper providing an external surface of the device, and means for attaching the bumper in overlaying relation to the casing including at least part of the side portion.

The location of the trim elements on the side portions of the device allows the trim to provide a defining outline separating the first and second faces and their respective functionalities while still maintaining their visual connection.

In addition, by providing additional detachable elements for a device the user is able to stamp his or her mark on the device by selecting different designs for trims enabling the devices to be distinguished despite their mass production.

Preferably the means for attaching comprises attachment elements on the obscured side of the bumper for cooperation with mating attachment elements on the casing of the handheld device. This enables the outer side of the bumper to be formed as desired enabling the surface to designed, for example, for grip.

For ease of removal, the means for attachment are desirably push-fit to allow the trims to be simply pulled off or pushed on as and when required by the user.

The bumper portion of the trim desirably extends to overlay the casing providing the first and second faces. This clearly enables the trim to provide a framing outline around the respective faces to unite them visually giving each of the prime operations of the respective faces preeminence depending upon which of the faces is operational.

When the bumper overlays an operating face of the casing i recessed to provide a smooth transition from the overlying portion of the bumper to the operating face.

The trim element is preferably formed from a flexible durable material having a low loss tangent. This ensures it does not interfer with any transmission properties of the device engine located in the casing. Flexibility allows the trim to be removed from the device without damage and durability enables the trim to be removed and reattached repeatedly without significant deterioration in the look or attachment properties of the device. It is particularly desirable that the fit of the trim to the casing does not deteriorate with repeated attachment and reattachment.

A suitable material has been found to be a thermoplastic alloy made up of ionomer & polyamide. A suitable example of this is Surlyn reflections SG201U NC010 manufactured by Du Pont which has a loss tangent of 0.002.

It is desirable that the trim maintains its shape when removed from the casing. This especially allows the element to be reattached with the minimum trouble in registration with the casing. When the trim has portions of C- or U-cross-section this is of particular advantage as the trim can be easily located with respect to the casing.

In embodiments of the invention the trim provides apertures for accessing keys located on the side portion of the casing. This enables the electronic device which the casing serves to provide a genuine dual A-side functionality, operation keys common to both functions can be accessed with equal ease from both sides. Some of the keys accessed through the trim may, however, have different functions for use in relation to each of the operating faces.

Respective trims may surround the full perimeter of the first face or may, as in embodiments illustrated in the application surround only a portion of the perimeter.

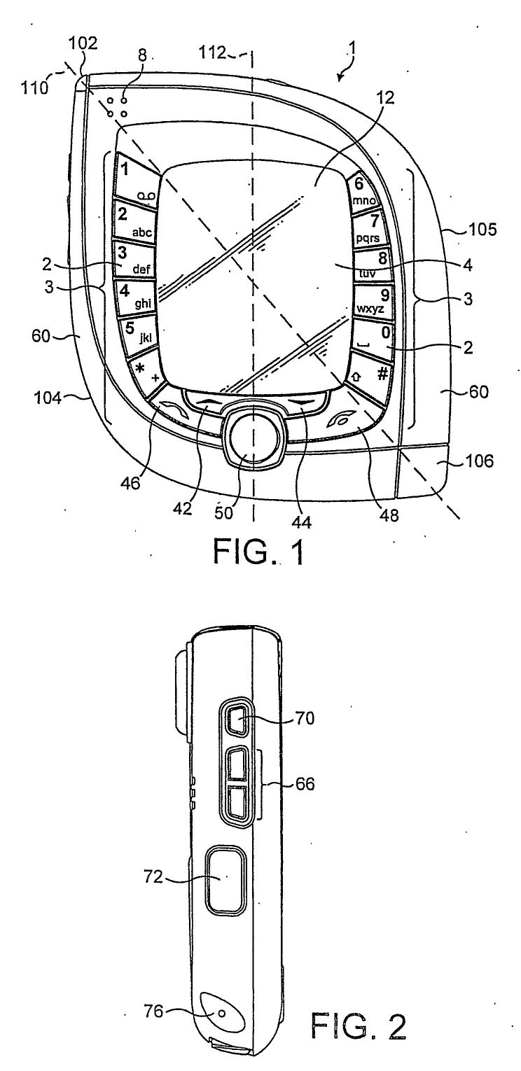

The invention will be described in greater detail with reference to FIGS. 1 to 8 of the accompanying drawings.

FIG. 1 is a plan view of a first face of an embodiment of the present invention;

FIG. 2 is a side view of embodiment of FIG. 1;

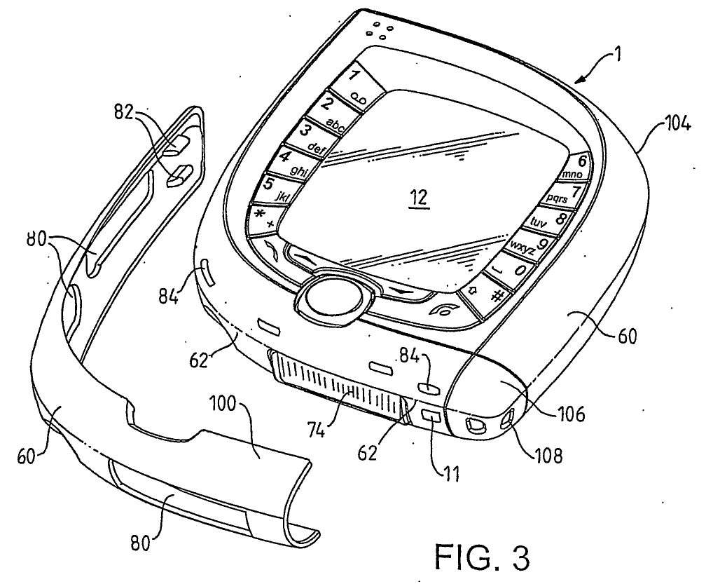

FIG. 3 is a persective view of the embodiment of FIG. 1 showing the same face with one of the trims exploded off;

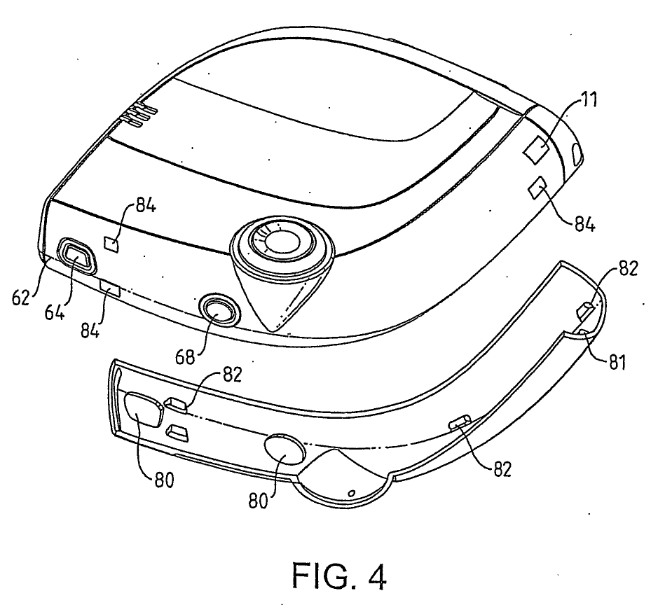

FIG. 4 is a perspective view of the camera face of the device with exploded trim;

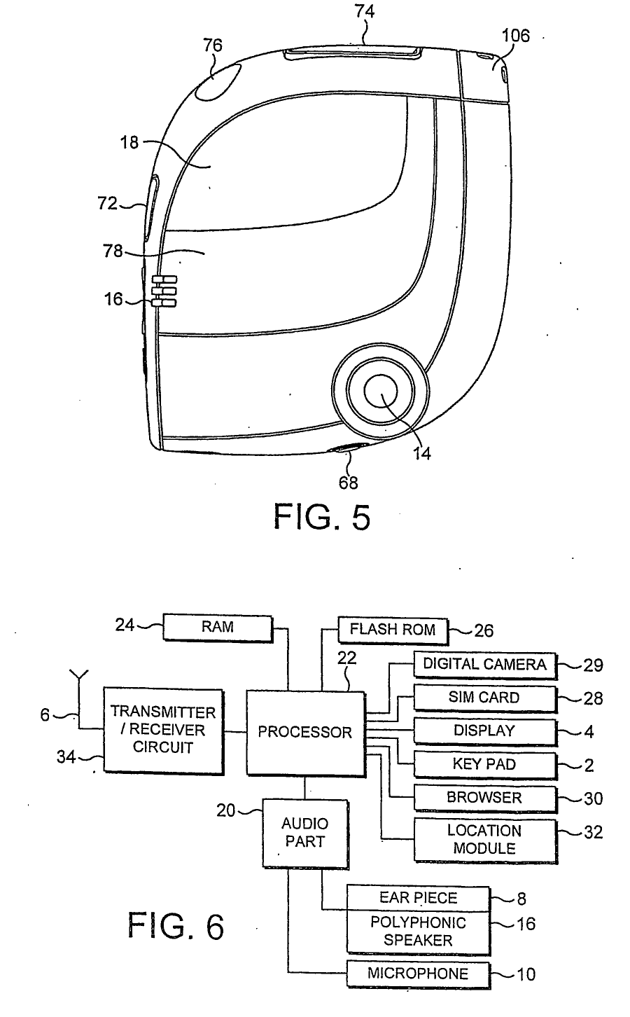

FIG. 5 is a plan view of a second camera face of the embodiment of FIG. 1;

FIG. 6 is a functional diagram showing the functional blocks of a communications device in accordance with embodiments of the invention;

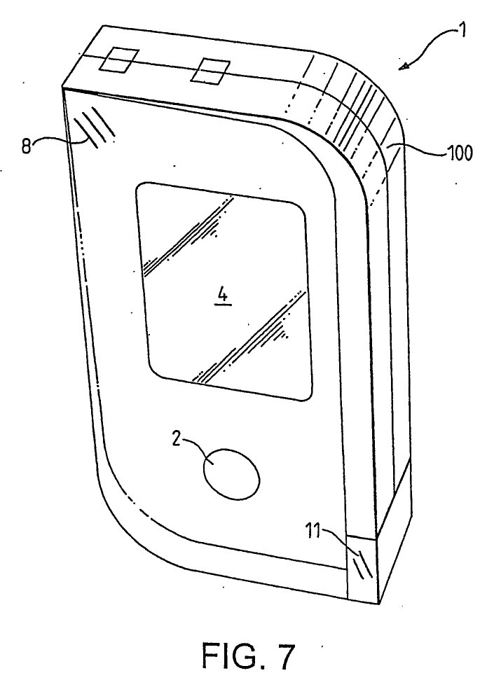

FIG. 7 is a perspective view of one face of another embodiment of the present invention having a different aspect ratio;

FIG. 8 is an illustration of an embodiment of the invention being viewed by a user; and

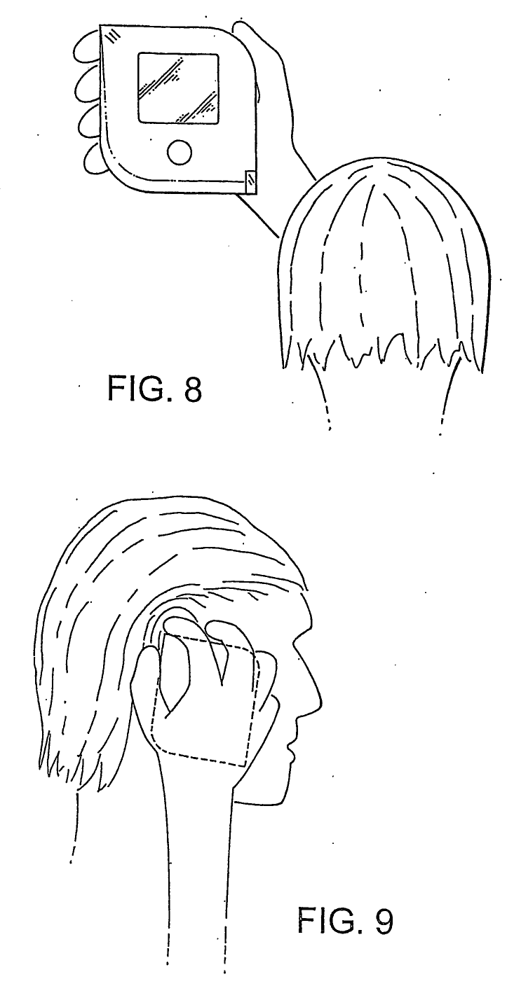

FIG. 9 is a representation of the device of FIG. 8 held to the ear of a user.

The handheld communications device illustrated in FIGS. 1 to 5 has two principle or main functions. In the example illustrated these are to make voice calls, for more traditional mobile phone functions, and to take photographs. The two functionalities may be supplemented by other functionalities known to the skilled man e.g. data communications, multi-media messaging, navigation etc. The functionalities can also be combined by, for example, taking a photograph and sending it to another via a data link. This may be an over the air link utilising the mobile communications facility of the device.

The functional aspects of the communication device can be seen in FIG. 6. The device 1 includes a key array 2, a display 4, an antenna 6, an ear piece and speaker 8 on a communications face 12 and a lens 14 of a digital camera 29 and polyphonic speaker 16 on the imaging face 18. The microphone 10 is towards the end of the casing and an aperture 11 is provided in the side of the casing to pick up the user's speech. A corresponding aperture 81 is provided in the trim. The microphone outlets are not directly located on the longest span of the device, but the benefit of the longer span is still enjoyed. The communication device 1 is adapted for communication via a wireless telecommunication network. The microphone records the users speech, and the analogue signals formed thereby are A/D converted by an A/D converter before the speech is encoded in an audio part 20. The encoded speech signal is transferred to processor 22. The processor may support software in the phone. The processor also forms the interface to peripheral units of the apparatus. These include a Random Access Memory (RAM) 24 and a Flash Read Only Memory (ROM) 26, a SIM card 28, the display 4, the digital camera 29 and the key array 2, and perhaps a browser application 30, and a location module 32.

The digital camera 29 allows the user to record images and provides suitable outputs to allow the download of the recorded images to a computer for manipulation and printing. The stored photographic data can also be sent to other destinations either over-the-air using the communications capability of the device or through a hardwired or landline link via e.g. the internet.

The processor communicates with a transceiver 34, e.g. a circuit, which is adapted to send and receive messages in a telecommunication network. The telecommunications network may be a GSM or W-CDMA network, but the invention may also be applied in connection with any other network, including but not limited to other kinds of wireless networks and various forms of cordless phone systems or in dual band phones accessing sets of these systems or networks. The audio part speech-decodes the signal, which is transferred from the processor to the earpiece via a D/A converter.

Devices according to embodiments of this invention may have a radical appearance. The casing does not have traditional mirror symmetry but is rather asymmetric although the main features of the design have predominantly 180 degree rotational symmetry.

There are two sides that would traditionally be termed A-sides. The first is the mobile phone/communications A-side 12. This can be seen in FIGS. 1 and 3. This side has ‘screen centricity’ i.e. there is a central screen. In the embodiment illustrated the input region includes a split keymat 3, with keys running either side of the screen 4. In one particular embodiment it is the alphanumeric keys that are split in this fashion. Other arrangements of the keys are clearly possible. The arrangement of the keys provides the advantage that they are close to the screen, this may be useful especially if a number of different softkeys are to be used in conjunction with the alpha numeric keys. Also in this particular embodiment the screen is in portrait, although other arrangements including a landscape arrangement are clearly within the scope of the skilled man. The orientation of the screen dictates the most comfortable viewing and data entry orientation of the device.

There may be additional functional keys 42, 44, 46, 48, 50 located to the bottom of the screen. These are placed in more traditional locations with the soft keys 42, 44 being located close to the screen. The send and end call buttons 46, 48 are also located below the screen. An 8-way key or joystick 50 may also be provided at the bottom of the screen for ease of input for e.g. playing games. Also on the communications face 12 are located the earpiece 8 and the mouth piece 10. These are diametrically opposed on the furthest corners of the device to provide maximum mouth to ear distance for voice calls.

On the imaging face 18, the lens 14 is provided for taking pictures. For the digital camera 29 of the present invention, the landscape display screen allows the photographer to see the image before the picture is taken. The lens could also be used for taking video footage. A view finder could be provided to supplement the digital display.

To promote the double A-side aspect of the described embodiment allowing the device to have two primary functionalities available to the user, a pair of trims 60 are provided around the edges of the device. The trim 60 is a bumper or buffer that hugs the sides of the device. The trim covers the split-lines 62 or seam between what would have traditionally been the A and B covers providing equal focus on or predominance to either of the major faces of the device. The trims 60 frame a region on each side of the device. On the communications A-side a frame surrounds the display 4 and input buttons. On the imaging A-side the same shaped frame surrounds the casing supporting the lens. As the frame provided by the trims 60 marks the same shaped boundary on each of the flat faces, the visual impact of each of the faces is similar and this enhances the dual aspect nature of the device. The clear separation of the main operating elements for the two principal functions of the device on to the respective A-sides enhances simple operation of the user interface. The two A-sides, could, however, be utilised to separate the functionality or operation of the device in ways other than mobile phone/photography.

The trims 60 protect the vulnerable edges and connection along the split-lines 62 of the casing parts reducing the likelihood of the elements breaking apart if the device is dropped or suffers an impact in another way. The trims 60 cushion the casing and also provide another texture that can be used to improve the grip or feel of the device. This is beneficial as the trim is located around the periphery of the device and is accordingly most likely to be gripped when the device is in use.

Problems arise with the design of the trim. It is desirably easily detachable and reattachable, wears well and does not deform on frequent release and reattachment. In the illustrated embodiment the trim is formed in two pieces. There is a snug fit between the trim and the intersection with the other exposed parts of the casing. The trim has flanges 100 at one end that overlap the casing of the front and rear faces providing a C- or U-shaped cross-section for part of its extent coming together at an abutment 102 at one extremity of the device. At this point in the illustrated embodiment the trim covers only the perpendicular side face of the device making a discontinuity where it meets each of the opposed A-faces of the device. The flat section ends of the trim meet at one extreme of the device. The abutment 102 is made neat by one of the trim elements overlying the other to provide a visually complete transition from one of the side sweeps 104, 105 to the other. At the other, in the position a tear duct would occupy in an eye of similar shape, a corner piece 106 is provided to seamlessly complete the enclosure. This corner piece provides a connection point 108 for a lanyard to allow the handset to be hung on a necklace around the user's neck or a bracelet around the user's wrist. The microphone 10 and apertures in the casing 11 and 81 are located in a region to the side of the corner pieces providing a far larger spacing than would be available along the upright viewing axis 112 that indicates the orientation for viewing the screen or operating the device, for example, using the key pad. The line between the ear piece and the speaker apertures provides an audio axis, 110 that is closely enough aligned with the diagonal to provide a significant increase in the mouth to ear distance over that available along the viewing axis.

To create seamless operating faces, the casing at the C-section regions of the trim are recessed to allow the trim to lie flush with each face. The trims 60 are attached to respective sides of the device as a mirror image along the major, in this case audio, axis 110.

Whilst covering the split-lines 62, the trim still allows access to an on/off key 64, volume/scroll key 66, camera function key 68, and voice tag key 70, known in Japan as a ‘yo be ba’ key all located on the side of the device. These keys are easily accessible when utilising either the mobile communication A-side or the imaging A-side and can be used in either circumstance. The operation associated with the keys located in the region of the trim may, however, differ for respective principal functions. For example the key 66 that allows volume regulation for the mobile communications function may provide contrast or other imaging function such as brightness, colour or zoom when operated when the device is operating in the photographic mode.

Also accessible through apertures in the trim in the illustrated embodiment of the invention are an infrared connector 72, an electrical connector 74, a jack for an earpiece 76, and the microphone aperture 10.

As well as covering the side split-line 62, the trim disguises the door of the battery compartment 78. This enhances the appearance of a double A-sided device as the only visible clue to the location of the battery, which is traditionally on the rear of a handset, is the line bounding the cover. This is further disguised in the illustrated embodiment with an echoing detail on the imaging face that draws the eye away from this feature. In the illustrated embodiment the trim must be removed before the battery compartment can be unlatched. Once the trim 60 has been removed, the battery compartment cover 78 can be drawn aside to allow access to the battery and the SIM card that is also preferably located below the battery for protection.

Preferably the trim is flexible and resilient and withstands tens of thousands of bends without marking. It also needs to be compatible with radio transmission from the handset. The material from which the trim is made has therefore been carefully selected to meet these criteria. The trim in this embodiment are from Surlyn reflections SG201U NC010 manufactured by Du Pont.

The material has the following properties:

Tensile Strength—44.8 Mpa

Elongation at break—>200%

Flexural Modulus—638J/m @ 23 C

IZOD impact—266 J/m @ 23 C

Vicat Softening—190 C

Specific Gravity—1.043

Loss Tangent—0.002

Although this is only one material suitable for the trim, other materials should provide at least substantially similar loss tangents and comparable flexibility, and resilience.

For user customisation and to allow, as already discussed, ready access to the battery compartment, the trim is desirably relatively easy to remove and remount. In embodiments of the invention, the trim is a push fit to the casing, requiring no other parts to be moved or altered in order for the trim to be attached or removed. In the illustrated embodiment of the invention the trim maintains its shape when removed from the handset making positioning the trim prior to attachment as simple as possible. The cut-outs 80 in the bumper also enable it to be correctly registered with the keys and other functional and non functional details exposed when the trim is in position. For connection between the trim and the main body of the device, connectors 82, 84 are positioned on both the trim and the casing. The clips 82 on the trim snap into place in apertures 84 on the body. Although in this embodiment the trim is shown with male parts and the device casing with female parts, this can be reversed. The arrangement of this embodiment does, however, have the advantage that with the trim being flexible the protruding pins are formed from a more flexible material than the casing elements that are providing the co-operating apertures.

Other arrangements including press-stud fitments have been envisaged for the connection between the trim and the supporting parts of the casing. In embodiments of the invention it is advantageous to provide a support structure to which the trim elements are connected as this provides some substance to what may otherwise be a rather flexible member in order to comply with the requirements of frequent attachment and detachment. The sides 90 seen in FIG. 4 and hidden by the trim 60 in FIG. 2 provide this function.

The removable trim provides a customisable part for a user to stamp individuality on the device. It is envisaged that replacement trims will be available in a variety of materials, colours, and textures. The texture of the trims may complement the manner of use of the device by, for example, enhancing the tactile feel of holding the device in the optimum orientation.

In embodiments of the invention the trim may have a leather outer surface. Other possibilities for the trim include having a material or plastic outer surface. To maintain the intrinsic shape of the trim preferably materials providing the outer surface of the trim will be mounted on a substrate having the desired electromagnetic and durability characteristics discussed earlier using, for example, a suitable adhesive.

The ambiguity in orientation lends itself to a twin axis approach to operation of the device. In the present embodiment the display is slightly portrait in aspect. When in the viewing orientation with the viewing axis 112 upright, the trims sweep around the bottom and left side and top and right side respectively, providing a device that instead of four sides has only two. The smooth sides promote convenient gripping of the device with the fingers along one side of the device and the thumb along the other. The upright sides allow the device to be gripped in this fashion with the hand held in a natural position for viewing while keeping the display in the correct orientation. The arrangement with two sweeping sides 104, 105 that provide either a top and a side region or a bottom and side region rather than two sides and a top and bottom allows the phone to be used in a more ergonomic fashion. It also allows the casing to be stretched along the audio axis, increasing the separation of the microphone and earpiece.

In arrangements of embodiments of the invention, the device can be moved from data input or operation input to in-call mode without the user having to rearrange the device in the hand. In data input mode if the device is held in the left hand, either the left thumb or the fingers of the right hand can be used for input, vice versa if the device is held in the right hand.

The vertical axis 112 through the display is not the same orientation as the line between the mouth and earpiece 110 located to a reasonable approximation on the furthest diametrically opposed corners of the device. Unusually, the vertical axis through the display is not, therefore, aligned with the ear when the device is held to the ear for communication. The design of the device does, however, allow the device to be moved from in front of the user's face to the user's ear without adjusting the position of the device in the user's hand. This can be seen most clearly in FIGS. 8 and 9 in which the main two holding positions of the device can be seen i.e. viewing/data input and talking/listening.

In use when the device is gripped by the upright trim sides (FIG. 8) the audio axis 110 is substantially aligned with the users forearm. This means that the wrist does not need to be moved to any great extent as the elbow is bent to move the handheld device to the ear. A slight variation in position of the wrist may be required, but generally the device can be moved from a position in which the display is being scrutinised, to the ear where a caller can be heard and the user's own speech picked up by the microphone with a mere movement of the elbow. The curved sweeps of the device allow it to fit-comfortably into the hand. The ergonomic design of the device allows the speaker to be carefully aligned between the fingers of the user when placed to the ear allowing it to be effectively and comfortably positioned for in-call use.

In the light of the foregoing description, it will be clear to the skilled man that various modifications may be made within the scope of the invention.

The present invention includes any novel feature or combination of features disclosed herein either explicitly or any generalisation thereof irrespective of whether or not it relates to the claimed invention or mitigates any or all of the problems addressed.

1. A detachable trim element for a handheld electronic device having a casing enclosing the engine of the device and providing first and second opposed faces bridged by a side portion, the trim element comprising a bumper providing an external surface of the device, and means for attaching the bumper in overlaying relation to the casing including at least part of the side portion.

2. A detachable trim element according to claim 1 wherein the means for attaching comprise attachment elements on the obscured side of the bumper for cooperation with mating attachment elements on the casing of the handheld device.

3. A detachable trim element according to claim 1 wherein male attachment elements are carried by the trim.

4. A detachable trim element according to claim 1 wherein the attachment means are arranged such that the user can remove the trim by pulling the attachment elements located on the bumper from engagement with the mating attachment elements on the casing.

5. A detachable trim element according to claim 1 wherein the attachment means are arranged such that the attach the trim by pushing the attachment elements located on the bumper into engagement with the mating attachment elements on the casing.

6. A detachable trim element according to claim 1 wherein the bumper extends to overlay the casing providing the first and second faces.

7. A detachable trim element according to claim 1 wherein the at least one of the first and second faces is recessed to provide a smooth transition from the overlying portion of the bumper to the face.

8. A detachable trim element according to preceding claim 1 wherein for regions of the trim, the bumper tapers to coincide in extent with the bridging side portions of the casing.

9. A detachable trim element according to claim 1 wherein for regions of the trim the bumper has a C-shaped cross-section to overlay the first and/or second faces of the device.

10. A detachable trim element according to claim 1 wherein the bumpers provide a gripping surface.

11. A detachable trim element according to claim 1 wherein the trim element is formed from a flexible durable material having a low loss tangent.

12. A detachable trim element according claim 11 wherein the loss tangent is around 0.002.

13. A detachable trim element according to claim 1 wherein the trim element is formed a material having substantially the properties of durability and loss tangent of Surlyn reflections SG201 U NC010 manufactured by Du Pont.

14. A detachable trim element according to claim 1 wherein at rest the trim element substantially maintains its shape when removed from the casing.

15. A detachable trim element according to any claim 1 wherein the bumper provides apertures for accessing keys located on the side portion of the casing.

16. A detachable trim element according to claim 1 wherein the side portion of the casing provides a side sweep defining the shape of the first face and the bumper is curved to follow the contour of the side sweep.

17. A casing for a handheld electronic device enclosing the engine of the device comprising first and second opposed faces bridged by a side portion, and a detachable trim element in accordance with claim 1.

18. A casing for a handheld electronic device in accordance with claim 17 wherein the first face defines a generally planar operating face for providing an input mechanism and a display region and having a first axis defining an operation orientation of the device, the side portions of the casing providing first and second side sweeps defining the shape of the generally planar operating face.

19. A casing for a handheld electronic device according to claim 18 wherein a trim hugs at least one of the side sweeps.

20. A casing for a handheld electronic device according to claim 18 wherein the generally planar operating face is substantially eye-shaped.

21. A casing for a handheld electronic device in accordance with claim 17 wherein both opposed faces provide operating faces with respective primary functions.

22. A casing for a handheld electronic device according to claim 17 wherein the trim defines a similar outline on both the first and second opposed faces.

23. A casing for a handheld electronic device according to claim 17 wherein the side portion of the casing provides a side sweep defining the shape of the first face and the bumper is curved to follow the contour of the side sweep and wherein respective trims hug respective ones of the side sweeps.

24. A casing for a handheld electronic device according to claim 23 wherein the respective trims together define outlines on the first and second faces of similar shape.

25. A casing for a handheld electronic device according to claim 23 wherein the first and second side sweeps confront each other at their respective ends defining the shape of the generally planar operating face and providing discontinuities at their respective confrontations.

26. A casing for a handheld electronic device according to claim 23 wherein the respective trims surround the full perimeter of the first face.

27. A casing for a handheld electronic device according to claim 23 wherein the respective trims engage respective portions of the full perimeter of the first face.

28. A casing for a handheld electronic device according to claim 23 wherein the respective trims meet at one of the confrontations.

29. A casing for a handheld electronic device according to claim 28 wherein the gap between the respective trims at the other of the confrontations is bridged by abasing element.

30. A casing for a handheld electronic device according to claim 29 wherein the casing element is a separate element.

31. A casing for a handheld electronic device according to claim 30 wherein the separate element is arranged for carrying a wrist strap.

32. A handheld electronic device comprising a casing according to claim 17.

33. (canceled)

34. (canceled)
